(19) United States
(12) Patent Application Publication
(10) Pub. No.: US 2010/0122458 A1
(43) Pub. Date: May 20, 2010

(54) PRINTED WIRING BOARD CONNECTOR PIN HAVING AN ACIRCULAR PROFILE

(75) Inventors: William L. Woods, JR., Kaufman, TX (US); Anthony Schneemann, Fomey, TX (US)

Correspondence Address: HITT GAINES P.C., P.O. BOX 832570, RICHARDSON, TX, 75083, US

(73) Assignee: Lineage Power Corporation, Mesquite, TX (US)

(21) Appl. No.: 12/273,618

(22) Filed: Nov. 19, 2008

(51) Int. Cl. H01R 43/00; H01R 12/00; H05K 1/11

(52) U.S. Cl. 29/884; 439/83; 174/262

(57) ABSTRACT

One aspect of this disclosure provides an electrical connector pin for a printed wiring board. This embodiment includes an unmachined, collar having an acircular configuration and including a side wall. This embodiment further includes a machined first cylindrical connector shaft integrally formed with the collar and extending from collar along the longitudinal axis, and a machined second cylindrical connector shaft integrally formed with the collar and extending from the collar and along the longitudinal axis in a direction opposite to that of the first cylindrical connector shaft.

### TECHNICAL FIELD

This application is directed, in general, to a connector pin for a printed wiring board and, more specifically, to a printed wiring board connector pin that has an acircular profile.

### BACKGROUND

Many current electronic product assemblies are manufactured from components or sub-assemblies provided to a manufacturer by a vendor/subcontractor. A common method of assembly of such products is to connect leads/terminals of the components or subsystem printed wiring assemblies (PWAs) onto the main system PWB by mass soldering. The two most common continuous mass soldering processes are wave soldering and reflow soldering. Wave soldering is commonly used when a high mix of through-hole components are involved in the product assemblies. Often, in such applications, the sub-assembly is connected to the main system PWB by one or more connector pins that are lathed from a cylindrical, material stock of conductive material, such as copper or aluminum. A segment of the connector pin is lathed from the cylindrical stock material to include a set-off or spacing segment. The spacer segment is lathed to have a diameter larger than the connecting via that goes through the PWB.

The spacer segment is typically seated against the surface of the main system and covers the connecting via. Due to this configuration, it is often difficult to get a lead-free solder to flow into the space between the wall of the via and the connector pin. This can result in a poor or inoperative connection. This flow problem has arisen recently due to the shift in the industry from lead based solders, which have a greater affinity of wetting the PWB than lead-free solders.

### SUMMARY

One aspect of this disclosure provides an electrical connector pin for a printed wiring board. This embodiment includes an unmachined, collar having an acircular configuration and including a side wall and first and second opposing planar faces perpendicular to a longitudinal axis of the collar. This embodiment further includes a machined first cylindrical connector shaft integrally formed with the collar and extending from the collar along the longitudinal axis, and a machined second cylindrical connector shaft integrally formed with the collar and extending from the collar and along the longitudinal axis in a direction opposite to that of the first cylindrical connector shaft.

Another aspect provides an electrical printed wiring board assembly. This embodiment comprises a first printed wiring board (PWB) having a via located therethrough and an electrical connector pin extending through the PWB. In one embodiment, the electrical connector pin comprises a collar having a sidewall that defines a perimeter of the collar. The sidewall has a bar stock profile that has a cross-section dimension perpendicular to a longitudinal axis of the bar stock that is less than a diameter of the via that forms a vent space between the via and a portion of the cross-section dimension. The connector pin further includes a machined first cylindrical connector shaft extending from the collar along the longitudinal axis. At least a portion of the connector shaft is received within the via and electrically connected to the PWB by a conductive material located within the via. The pin further includes a machined second cylindrical connector shaft extending from the collar along the longitudinal axis in a direction opposite to that of the first cylindrical connector shaft.

Another embodiment provides a method of fabricating an electrical assembly. This embodiment comprises providing a bar stock of a conductive material, wherein the bar stock has an acircular profile. Portions of the bar stock are removed to leave a collar having a sidewall that defines a perimeter of the collar and an acircular profile. The removal step forms a machined first cylindrical connector shaft integrally formed with the collar and extending from the collar along the longitudinal axis and a machined second cylindrical connector shaft integrally formed with the collar and extending from the collar along the longitudinal axis in a direction opposite to the first cylindrical connector shaft. The method further includes placing the first cylindrical connector shaft into a via of a first printed wiring board (PWB), such that at least a portion of the first cylindrical connector shaft is located within the via and electrically coupling the first cylindrical connector shaft to the PWB.

### BRIEF DESCRIPTION

Reference is now made to the following descriptions taken in conjunction with the accompanying drawings, in which:

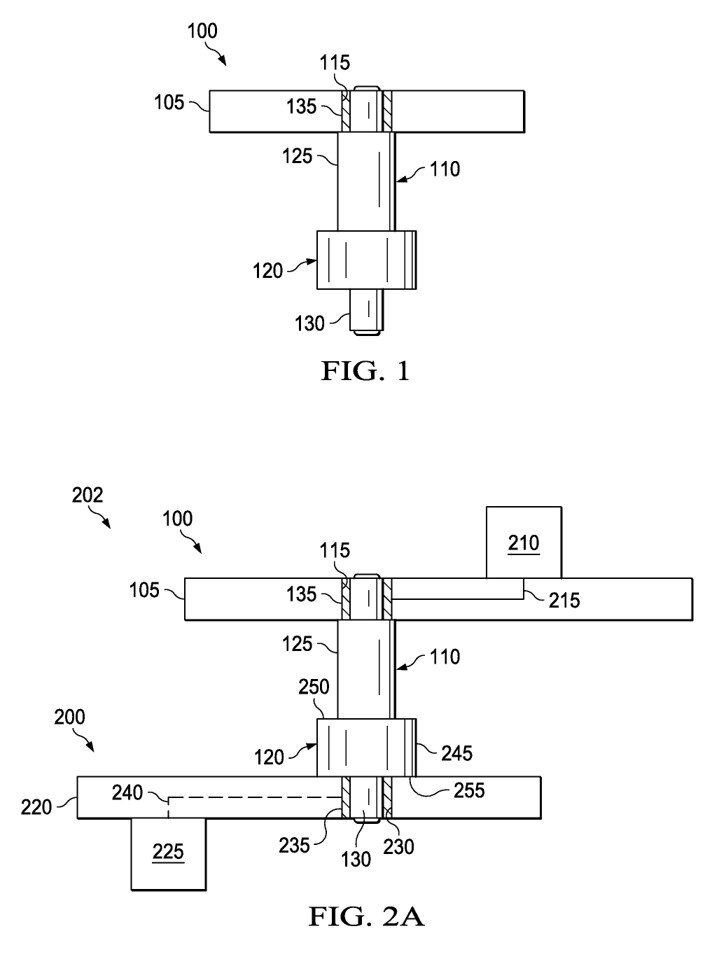

FIG. 1 illustrates a sub-assembly and an embodiment of a connector pin as provided herein;

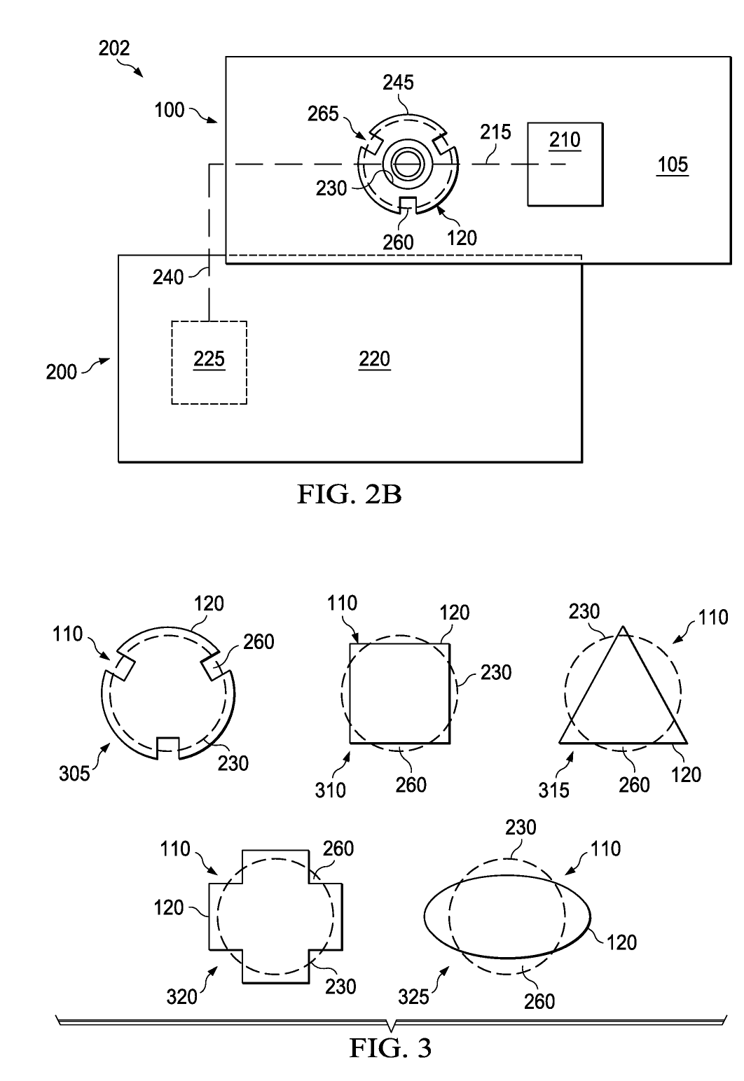

FIG. 2A illustrates the sub-assembly and connector pin of FIG. 1 connected to a main printed wiring board to form an electrical printed wiring board assembly;

FIG. 2B illustrates an overhead view of the assembly of FIG. 2A.

FIG. 3 illustrates different embodiments of collar pin having acircular profiles;

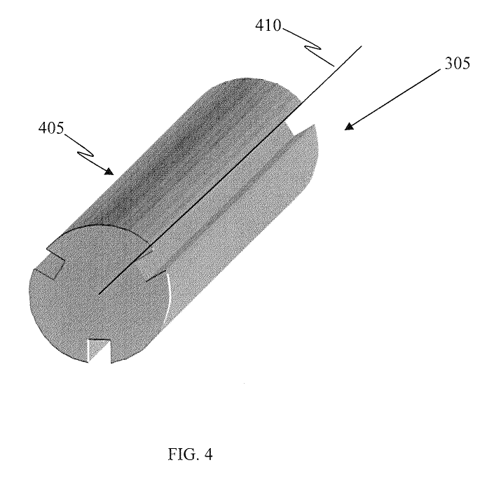

FIG. 4 illustrates a perspective view of a bar stock having one acircular configuration;

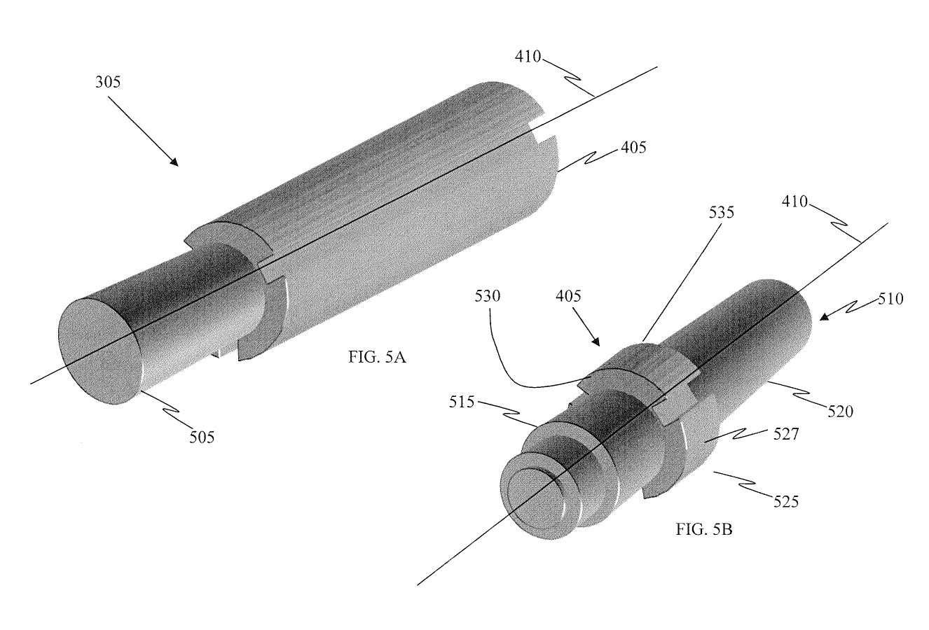

FIGS. 5A-5B illustrate perspective views of the formation of a connector pin from a bar stock; and

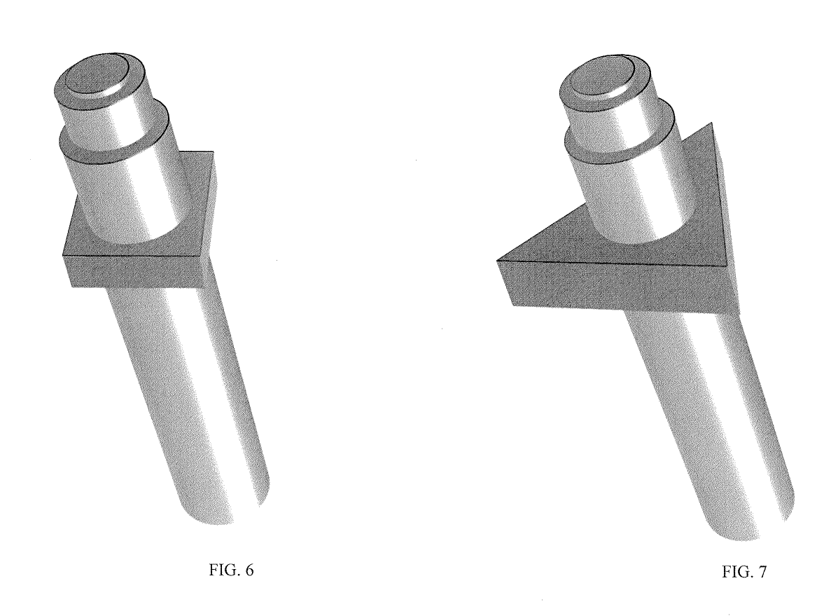

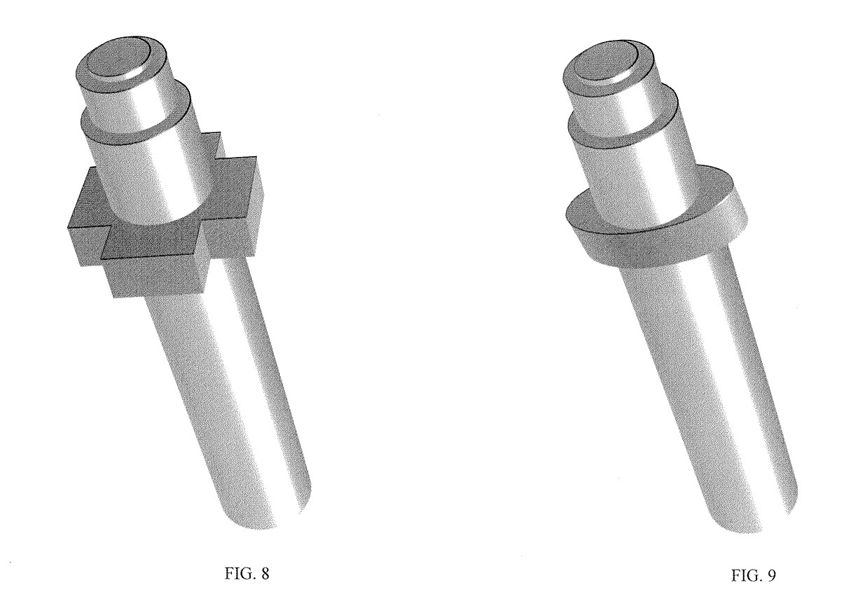

FIGS. 6-9 illustrate embodiments of different pin configurations having collars with acircular profiles.

### DETAILED DESCRIPTION

FIG. 1 illustrates one embodiment of a printed wiring board (PWB) sub-assembly 100. In this embodiment, the assembly 100 includes a PWB 105 and a connector pin 110. The PWB 105 may be of conventional design and has at least one via 115 located in the PWB 105. The electrical applications that can benefit from the embodiments of this disclosure may vary greatly, and though the discussions herein are directed to a sub-assembly PWB for a power supply, many other electrical applications are also within the scope of this disclosure. The connector pin 110 includes a collar 120 and first and second cylindrical connector shafts 125 and 130 that are coupled to the collar 120. As seen in this embodiment, at least a portion of the first cylindrical connector shaft 125 is received within the via 115 and is coupled to the PWB 105 within the via 115 by a solder joint 135.

As discussed below, the collar 120 has an acircular cross-sectional profile such that a portion of the perimeter of the collar 120 is less than a diameter of a via in which the connector pin 110 is inserted. The acircular profile provides a vent through which air may escape, which allows solder to more readily flow between the connector pin and the via. Since the acircular profile can be achieved without the need of machining, the cost and time of manufacture is advantageously reduced.

The acircular profile is original to the material stock or bar stock that is provided (e.g. either obtained from an internal supplier or from an outside supplier) and from which the connector pin 110 is made. As such, the collar 120 is not machined, or “unmachined,” during the formation of the connector pin 110. That is, the original or bar stock material that makes up the collar 120 is not cut or substantially removed such that the original surface profile of the collar 120 is left substantially unchanged or unaltered. For example, drilling a hole in the collar 120 or merely marring the surface does not substantially change the original surface profile. Moreover, the collar is considered not to be machined in those instances where the collar is merely buffed, polished, otherwise smoothed, or is left substantially unchanged.

This is in contrast to conventional connector pins that are typically formed from a circular stock, which results in a circular collar. In such instances, the manufacturers must perform additional machining steps by removing a portion of or beveling an edge of the collar such that a vent is formed between the via of the PWB and the collar. These additional manufacturing steps add cost and time to the manufacturing, which are undesirable.

FIG. 2A illustrates another embodiment wherein the PWB sub-assembly 100 is coupled to a main PWB assembly 200 by the connector pin 110 to form a PWB assembly 202. In this embodiment, the PWB sub-assembly 100 may include a conventional power supply 210 that is electrically connected to the connector pin 110 by one or more conductive traces 215 located within the PWB 105. The main PWB assembly 200 includes a conventional PWB 220, which may be designed to include many other conventional electrical components, which are generally designated by the box 225. As seen in FIG. 2A, the second cylindrical connector shaft 130 is at least partially received in a via 230 located within the PWB 220 and is coupled to the PWB 220 within the via 230 by a joint 235. In a preferred embodiment, the joint 235 is formed with a lead-free solder. However, in other embodiments other conventional solders, such as lead based solder, may be used. The second cylindrical connector shaft 130 is electrically connected to the electrical component 225 by one or more conductive traces 240.

As seen in this embodiment, the collar 120 includes a sidewall 245 and first and second faces 250, 255, in which the second face 255 contacts the surface of the PWB 220. For purposes discussed herein, the second face 255 is considered to contact the surface of the PWB 220 even though it does not contact the surface of the PWB 220 directly, for example, a thin layer of solder (not shown) may be located between these two structures.

FIG. 2B illustrates an overhead view of the PWB assembly 202. In this embodiment, the collar 120 has an acircular profile such that portions of the perimeter of the sidewall 245 of the collar 120 do not cover the via 230. As such, one or more vents or spaces 260 are formed between the portion of the sidewall 245 of the collar 120 and the via 230, which allow for air to escape during the soldering process. In this particular embodiment, the acircular profile is the notches 265 formed in the sidewall 245 such that a portion of the perimeter of the collar 120 does not extend over the via 230. Other embodiments of the acircular profile are discussed below regarding FIG. 3.

The presence of the vents or spaces 260 are important because industry standards prefer to not use lead based solder for environmental concerns and have turned to the use of lead-free solders that have a high percentage of tin. Lead based solders had the capacity to wet the inside of the via more readily than lead-free solders. Thus, when lead based solders were used, the solder was still able to move up into the space between the via and the connector pin. However, since lead-free solders do no wet as easily, the vent is necessary to allow the air to escape and thereby allow the lead-free solder to move into the space between the via and connector pin more readily.

FIG. 3 illustrates overhead views of cross-sections of various acircular configurations of the collar 120 of the connector pin 110. These cross-section are taken though a plane perpendicular to a longitudinal axis of the collar 120. For example, in embodiment 305, the collar 120 may have a notched configuration that presents a clover leaf-type cross section. The via 230 in the assembly PWB 200 is shown in a dashed line. As seen in this embodiment, portions of the perimeter of the sidewall of the collar 120 do not over lap the via 230. Thus, the vents 260, as discussed above, are formed.

In embodiment 310, the collar 120 may have a square-shaped cross-section or configuration. The via 230 in the assembly PWB 200 is shown in a dashed line. As seen in this embodiment, portions of the perimeter of the sidewall of the collar 120 do not over lap the via 230. Thus, the vents 260, as discussed above are formed.

In embodiment 315, the collar 120 may have a triangular-shaped cross-section or configuration. It should be noted that the acircular configurations disclosed herein may also include those embodiments where the sidewalls of the collar 120 may be curved. For example, embodiment 315 may also include a Reuleaux triangle shaped cross-section. The via 230 in the assembly PWB 200 is shown in a dashed line. As seen in this embodiment, portions of the perimeter of the sidewall of the collar 120 do not over lap the via 230. Thus, the vents 260, as discussed above are formed.

In embodiment 320, the collar 120 may have a cross-shaped cross-section or configuration. The via 230 in the assembly PWB 200 is shown in a dashed line. As seen in this embodiment, portions of the perimeter of the sidewall of the collar 120 do not over lap the via 230. Thus, the vents 260, as discussed above are formed. The foregoing examples illustrate different polygon shapes that may be used to construct the connector pin 110.

In another embodiment 325, the collar 120 may have an elliptical or oval-shape cross-section or configuration. The via 230 in the assembly PWB 200 is shown in a dashed line. As seen in this embodiment, portion of the perimeter of the sidewall of the collar do not overlap the via 230. Thus, the vents 260, as discussed above are formed.

As mentioned above, it is important to note that, unlike conventional pins, no additional machining is required to form the collars of these various embodiments, since the virgin or original profile of the bar stock material can be used to form the vent. Further, it should be understood that the foregoing are given as examples only and that many other acircular shapes are within the scope of this disclosure.

FIG. 4 is a perspective view of a bar or rod (referred to herein as bar stock 405) material that has an acircular cross-section or surface profile, as discussed above regarding embodiment 305 of FIG. 3, and also has a longitudinal axis 410. The bar stock 405 may be obtained from a supplier of such materials, either internally or externally to the manufacturer. As mentioned above, this surface profile presents a cross-sectional profile such that vents can be formed with a PWB. The material is comprised of a conductive material, such as metal, examples of which may include cooper, aluminum, or other materials from which electrical connector pins can be made.

FIGS. 5A-5B shows two perspective views of the embodiment 305 bar stock 405. FIG. 5A shows the bar stock 405 after a portion of the bar stock 405 has been machined or removed to form a first cylindrical shaft 505 of the connector pin. The machine or lathe used to remove the portion of the bar stock 405 is set to achieve the overall desired pin length and collar dimensions. The various dimensions of the pin are laid out and machining continues on the bar stock 405 to arrive at the connector pin configuration 510 shown in FIG. 5B. In this embodiment, the connector pin 510 includes a machined first cylindrical connector shaft 515 and a machined second cylindrical connector shaft 520, which are coupled to a collar 525. In one advantageous embodiment, the first and second cylindrical connector shafts 515, 520 are integrally formed with the collar 525. In other embodiments, the first and second connector shafts 515, 520 may be coupled to the collar 525, for example by cooperating threads or may be solder or welded together. The collar 525 is not machined, and thus, retains its original acircular surface profile. In an advantageous embodiment, the entire sidewall 527 of the collar 525 has the original acircular profile. The collar 525 has opposing first and second surfaces 530, 535 from which the first and second cylindrical connector shafts 515, 520 respectively extend along the longitudinal axis 410 in opposing directions. The connector pin 510 may be employed in the way described above to achieve the stated advantages. As seen, the cylindrical shafts 515, 520 may either be tapered or non-tapered.

FIGS. 6-9, which relate to embodiments illustrated in FIG. 3, show perspective views of various connector pin configurations that have collars with different types of acircular cross-sections. As discussed above regarding FIG. 3, all of these embodiments provide a connector pin that have a collar with an a circular cross-sectional profile, wherein at least a portion of a perimeter of the profile is less than a diameter of a via located in a PWB. As such, vents are inherently formed.

It has been found that significant manufacturing costs and time can be saved in manufacturing the connector pins covered by this disclosure. For example, it has been unexpectedly found that the effort to produce the pin is reduced by about 20% when using the principles discussed herein. The savings achieved by this 20% reduction are substantial and particularly advantageous when large numbers of pins must be produced. Moreover, choosing an acircular profile is counter-intuitive to standard manufacturing procedures because it is typically desirable to begin with a circular bar stock since the connector pin is to have circular connector shafts. Thus, those who are skilled in the art would not seek to use a bar stock with an acircular configuration absent the teachings of this disclosure.

Those skilled in the art to which this application relates will appreciate that other and further additions, deletions, substitutions and modifications may be made to the described embodiments.

What is claimed is:

1. An electrical connector pin for a printed wiring board, comprising:
an unmachined, collar having an acircular configuration and including a side wall;
a machined first cylindrical connector shaft integrally formed with the collar and extending from the collar along the longitudinal axis; and
a machined second cylindrical connector shaft integrally formed with the collar and extending from the collar in a direction opposite to that of the first cylindrical shaft.

2. The electrical connector pin recited in claim 1 wherein the acircular configuration is a polygon.

3. The electrical connector pin recited in claim 2, wherein the polygon is triangular shaped or square shaped.

4. The electrical connector pin recited in claim 3, wherein the acircular configuration includes at least one notch located in an outer surface of the collar and extending along the longitudinal axis thereof.

5. The electrical connector pin recited in claim 1, wherein the acircular configuration is elliptical.

6. An electrical printed wiring board assembly, comprising:
a first printed wiring board (PWB) having a via located therethrough; and
an electrical connector pin extending through the PWB, comprising:
a collar having a sidewall that defines a perimeter of the collar, the sidewall having a bar stock profile that has a cross-section dimension perpendicular to a longitudinal axis of the bar stock that is less than a diameter of the via that forms a vent space between via and a portion of the cross-section dimension;
a machined first cylindrical connector shaft extending from the collar along the longitudinal axis and at least a portion of which is received within the via and electrically connected to the PWB by a conductive material located within the via; and
a machined second cylindrical connector shaft extending from collar along the longitudinal axis in a direction opposite to that of the first cylindrical connector shaft.

7. The electrical assembly recited in claim 6 wherein bar stock profile is a polygon.

8. The electrical assembly recited in claim 7, wherein the polygon is triangular shaped or square shaped.

9. The electrical assembly recited in claim 7, wherein the bar stock profile includes at least one notch located in an outer surface of the collar and that extends along the entire longitudinal axis thereof.

10. The electrical assembly recited in claim 6, further including a power supply located on the PWB and electrically connected to the first cylindrical connector shaft.

11. The electrical assembly recited in claim 6, further including a second PWB having a via extending therethrough, wherein the collar contacts a surface of the second PWB and the second cylindrical connector shaft is received within the via of and electrically connected to the second PWB.

12. A method of fabricating an electrical assembly, comprising:
providing a bar stock of a conductive material, the bar stock having an acircular profile;
removing portions of the bar stock to leave a collar having a sidewall that defines a perimeter of the collar, the sidewall having the acircular profile, the removing forming;
a machined first cylindrical connector shaft integrally formed with the collar and extending from the collar along the longitudinal axis; and
a machined second cylindrical, connector shaft integrally formed with the collar and extending from the collar and along the longitudinal axis in a direction opposite to the first cylindrical connector shaft;
placing the first cylindrical connector shaft into a via of a first printed wiring board (PWB), such that at least a portion of the first cylindrical connector shaft is located within the via; and
electrically coupling the first cylindrical connector shaft to the PWB.

13. The method recited in claim 12, wherein electrically coupling includes soldering the first cylindrical connector shaft within the via.

14. The method recited in claim 12, wherein removing includes machining portions of the bar stock to form the first and second cylindrical connector shafts.

15. The method recited in claim 12, wherein the bar stock has an acircular profile and includes a bar stock having a polygon profile or an elliptical profile.

16. The method recited in claim 15, wherein the polygon profile is triangularly shaped or square shaped.

17. The method recited in claim 16, wherein the polygon profile includes at least one notch located in an outer surface of the collar and extending along the longitudinal axis thereof.

18. The method recited in claim 12, further including coupling a power supply located to the first PWB and electrically connecting the power supply to the first cylindrical connector shaft.

19. The method recited in claim 12, further including placing the second cylindrical connector shaft into a via of a second PWB, wherein the collar contacts a surface of the second PWB and electrically connecting the second cylindrical connector shaft to the second PWB, the acircular profile having a cross-section dimension perpendicular to the longitudinal axis of the bar stock that is less than a diameter of the via such that a vent space is formed between via and the cross-section dimension.

20. The method recited in claim 19, wherein electrically connecting the second cylindrical connector shaft to the second PWB includes soldering the second cylindrical connector shaft within the via of the second PWB.
